(19) United States
(12) Patent Application Publication
(10) Pub. No.: US 2024/0047432 A1
(43) Pub. Date: Feb. 8, 2024

(54) SEMICONDUCTOR DEVICE

(71) Applicant: ROHM CO., LTD., Kyoto-shi (JP)

(72) Inventor: Soichiro TAKAHASHI, Kyoto-shi (JP)

(21) Appl. No.: 18/491,332

(22) Filed: Oct. 20, 2023

Related U.S. Application Data
(63) Continuation of application No. PCT/JP2022/019913, filed on May 11, 2022.

(30) Foreign Application Priority Data
Jun. 2, 2021 (JP) 2021-093072

(51) Int. Cl. H01L 25/07; H01L 23/00; H01L 23/498; H01L 23/373

(52) U.S. Cl. CPC H01L 25/072; H01L 24/32; H01L 23/49822; H01L 23/3735; H01L 2224/32225

(57) ABSTRACT

A semiconductor device includes a substrate including an obverse surface facing one side in a thickness direction, a plurality of semiconductor elements located on the one side in the thickness direction with respect to the substrate and having a switching function, a first layer located between the obverse surface and the plurality of semiconductor elements in the thickness direction and having electrical conductivity, a second layer conductively bonding the obverse surface and the first layer to each other, and a third layer conductively bonding the first layer and the plurality of semiconductor elements to each other.

### TECHNICAL FIELD

The present disclosure relates to a semiconductor device.

### BACKGROUND ART

Conventionally, semiconductor device with semiconductor elements such as MOSFETs or IGBTs are widely known. In recent years, there has been an increasing demand for semiconductor devices capable of passing a large current. As a response to such a demand, JP-A-2018-182330 discloses a semiconductor device with a plurality of semiconductor elements such as MOSFETs. In the semiconductor device, a metal layer formed from a thin metal film such as copper foil is disposed on a substrate (insulating layer) made of an electrically insulating material. The semiconductor elements are conductively bonded to the metal layer via a conductive bonding layer such as solder. Such a semiconductor device can be easily adapted for a large current by increasing the number of semiconductor elements, for example.

During the use of the semiconductor device disclosed in JP-A-2018-182330, heat is generated from the semiconductor elements. The thermal conductivity of the substrate (insulating layer) is lower than that of the metal layer on which the semiconductor elements are mounted. Therefore, it takes time to dissipate the heat generated by the semiconductor elements to the opposite side of the substrate (insulating layer) from the metal layer. Thus, the heat generated at the semiconductor elements tends to be retained in the metal layer, causing an increase in temperature of the metal layer or the semiconductor elements.

### BRIEF DESCRIPTION OF THE DRAWINGS

FIG. 1 is a perspective view of a semiconductor device according to a first embodiment of the present disclosure.

FIG. 2 is a plan view of the semiconductor device shown in FIG. 1.

FIG. 3 is a perspective view (through a sealing resin and wires) of the semiconductor device shown in FIG. 1.

FIG. 4 is a plan view (through the sealing resin) of the semiconductor device shown in FIG. 1.

FIG. 5 is a front view of the semiconductor device shown in FIG. 1.

FIG. 6 is a right side view of the semiconductor device shown in FIG. 1.

FIG. 7 is a left side view of the semiconductor device shown in FIG. 1.

FIG. 8 is a bottom view of the semiconductor device shown in FIG. 1.

FIG. 9 is an enlarged view of the right side of FIG. 4.

FIG. 10 is an enlarged view of the left side of FIG. 4.

FIG. 11 is a sectional view taken along line XI-XI in FIG. 4.

FIG. 12 is a sectional view taken along line XII-XII in FIG. 4.

FIG. 13 is a sectional view taken along line XIII-XIII in FIG. 4.

FIG. 14 is a sectional view taken along line XIV-XIV in FIG. 4.

FIG. 15 is an enlarged view of a portion (around a first element) of FIG. 9.

FIG. 16 is a sectional view taken along line XVI-XVI in FIG. 15.

FIG. 17 is an enlarged view of a portion (around a second element) of FIG. 9.

FIG. 18 is a sectional view taken along line XVIII-XVIII in FIG. 17.

FIG. 19 is a plan view (through the sealing resin) of a semiconductor device according to a variation of the first embodiment.

FIG. 20 is an enlarged view of a portion (around a first element) of FIG. 19.

FIG. 21 is a sectional view taken along line XXI-XXI in FIG. 20.

FIG. 22 is an enlarged view of a portion (around a second element) of FIG. 19.

FIG. 23 is a sectional view taken along line XXIII-XXIII in FIG. 22.

FIG. 24 is a plan view (through the sealing resin) of a semiconductor device according to a second embodiment of the present disclosure.

FIG. 25 is an enlarged view of the right side of FIG. 24.

FIG. 26 is a sectional view taken along line XXVI-XXVI in FIG. 24.

### DETAILED DESCRIPTION OF EMBODIMENTS

The following describes preferred embodiments of the present disclosure with reference to the drawings.

In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”.

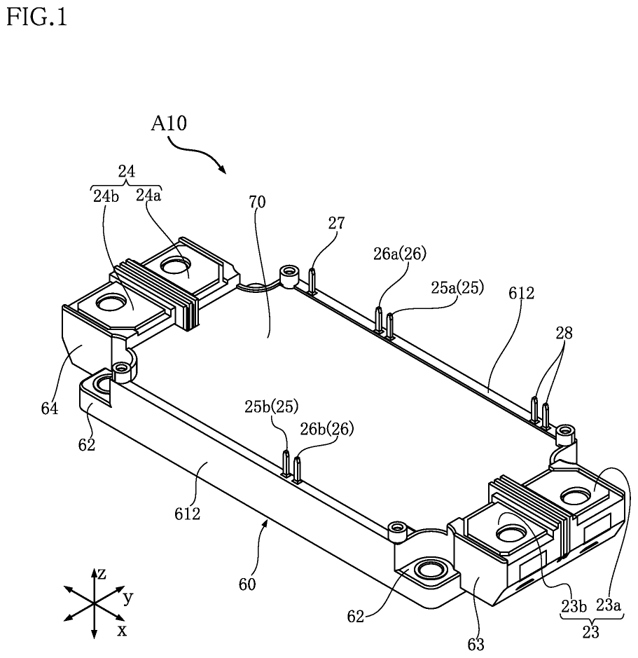

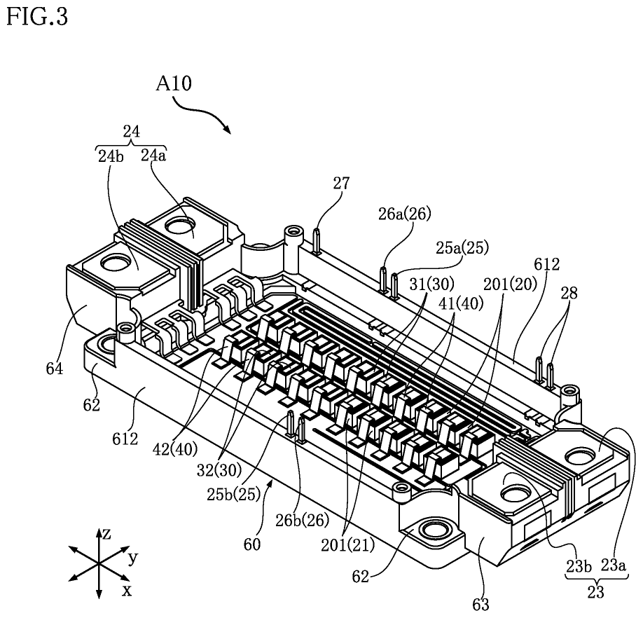

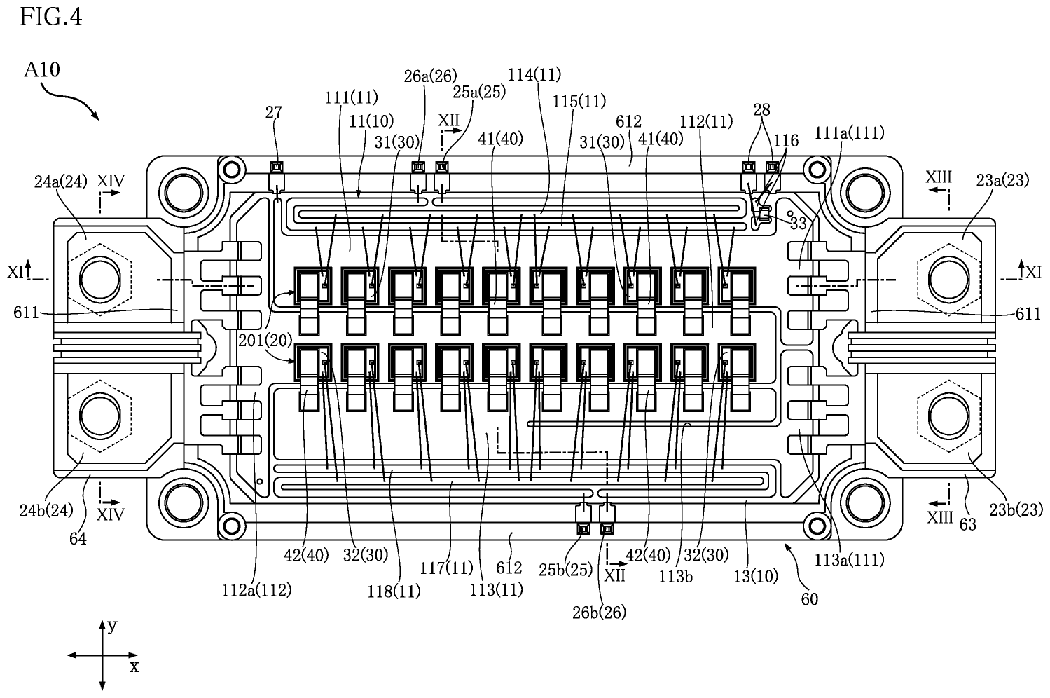

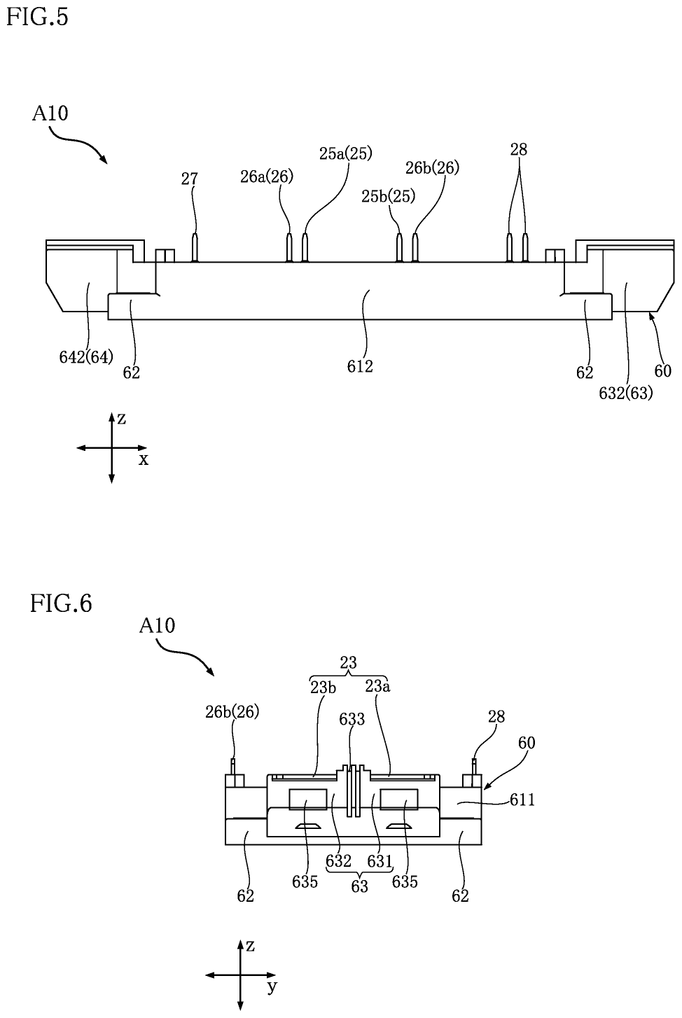

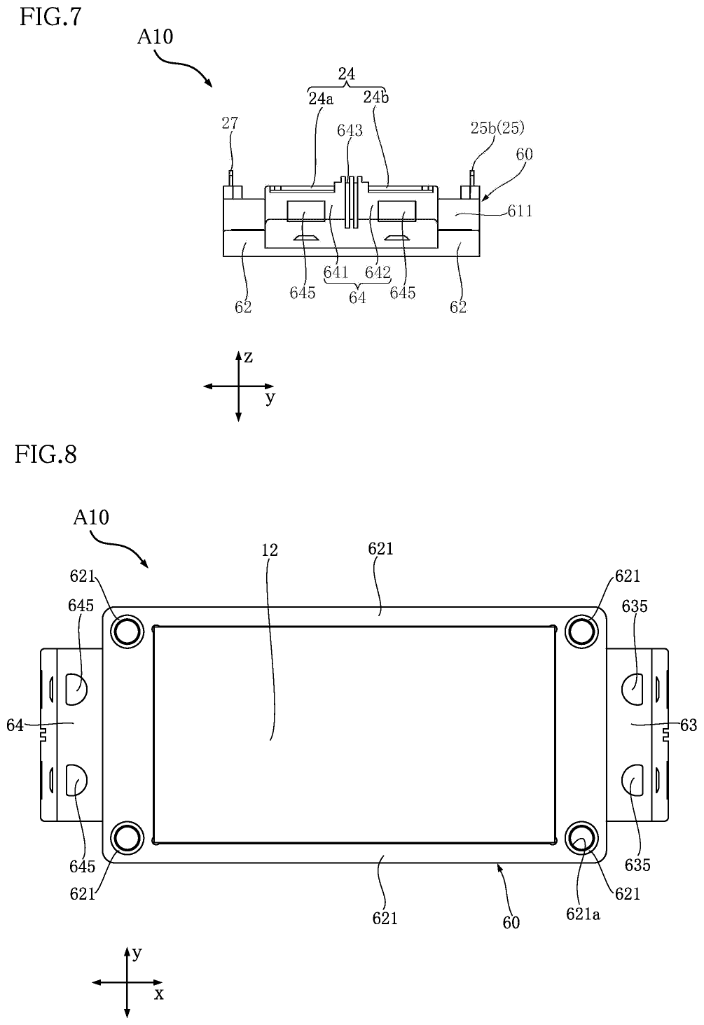

Based on FIGS. 1 to 18, a semiconductor device A10 according to a first embodiment of the present disclosure is described below. The semiconductor device A10 includes a substrate 10, a first layer 20, a second layer 21, a third layer 22, and a plurality of semiconductor elements 30. In the present embodiment, the semiconductor device A10 includes a plurality of power supply terminals 23, an output terminal 24, a plurality of gate terminals 25, a plurality of element current detection terminals 26, a plurality of conductive members 40, a case 60, and a sealing resin 70. For the convenience of understanding, the sealing resin 70 and the wires, described later, are transparent in FIG. 3. The sealing resin 70 is transparent in FIG. 4.

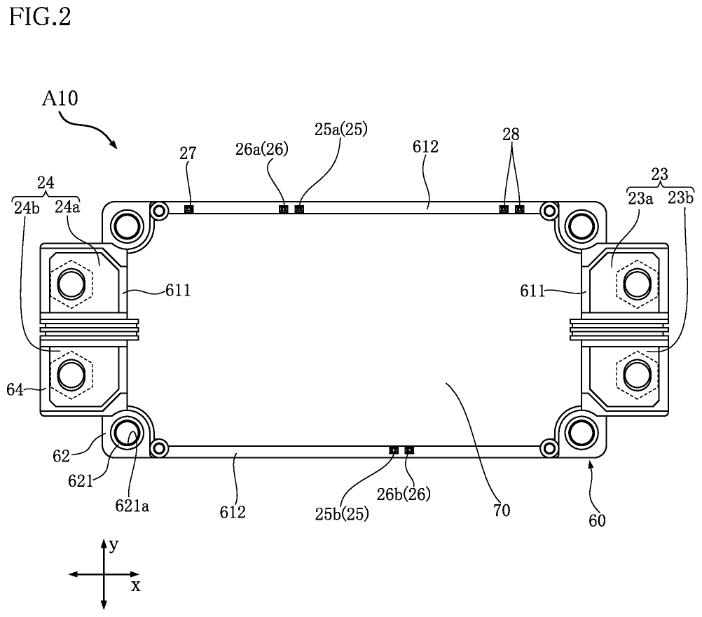

The semiconductor device A10 shown in FIG. 1 is a power module. The semiconductor device A10 is used in inverters for various electrical products and hybrid vehicles. As shown in FIGS. 1 and 2, the semiconductor device A10 is rectangular (or generally rectangular) as viewed in the thickness direction z of the substrate 10. For the convenience of description, a direction orthogonal to the thickness direction z is defined as a first direction x. The direction orthogonal to the thickness direction z and the first direction x is defined as a second direction y. The semiconductor device A10 is elongated along the first direction x in the illustrated example, but the present disclosure is not limited to this.

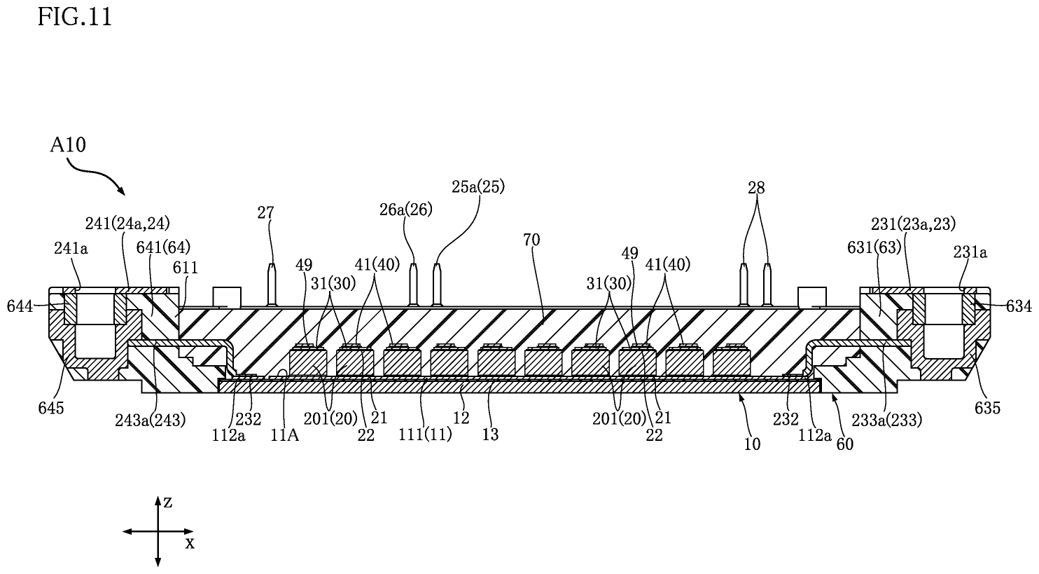

As shown in FIG. 11, the substrate 10 has a first metal layer 11, a second metal layer 12, and an insulating layer 13. The insulating layer 13 is located between the first metal layer 11 and the second metal layer 12 in the thickness direction z. The insulating layer 13 has an electrically insulating property. Examples of the constituent material of the insulating layer 13 include ceramic epoxy.

The first metal layer 11 is laminated on the insulating layer 13. The first metal layer 11 includes an obverse surface 11A. The obverse surface 11A faces a first side (the upper side in FIG. 11) in the thickness direction z. The first metal layer 11 is made of a metal material having electrical conductivity and composed of metal foil of copper (Cu) or a copper alloy, for example.

The second metal layer 12 is located opposite to the first metal layer 11 (on a second side in the thickness direction z) with respect to the insulating layer 13. The insulating layer 13 is laminated on the second metal layer 12. The second metal layer 12 is made of a metal having electrical conductivity as with the first metal layer 11 and formed from a metal plate made of copper or a copper alloy, for example.

As an example of the thicknesses of the first metal layer 11, the second metal layer 12 and the insulating layer 13, the thickness of the first metal layer 11 may be 0.1 mm to 2.0 mm, the thickness of the second metal layer 12 may be 0.3 mm to 2.0 mm, and the thickness of the insulating layer 13 may be 0.12 mm to 0.18 mm. An insulated metal substrate may be used as the substrate 10 of the present embodiment. The substrate 10 provided by an insulated metal substrate is composed of a metal plate (the second metal layer 12), and the insulating layer 13 and the first metal layer 11 laminated on the metal plate. Instead of an insulated metal substrate, a DBC (Direct Bonded Copper) substrate may be used. The DBC substrate is composed of a ceramic plate (the insulating layer 13) and a pair of copper foils (the first metal layer 11 and the second metal layer 12) laminated on opposite sides of the ceramic plate in the thickness direction z.

In the present embodiment, the first metal layer 11 includes a first element mount section 111, a second element mount section 112, a first conductive section 113, a first gate section 114, a first detection section 115, a pair of thermistor mount sections 116, a second gate section 117, and a second detection section 118. Such sections constituting the first metal layer 11 are formed, for example, by partially removing the copper foil laminated on the insulating layer 13 through wet etching. The surfaces of these sections of the first metal layer 11 may be plated with silver (Ag).

As shown in FIGS. 4 and 9 to 12, some of the semiconductor elements 30 are mounted on the first element mount section 111. For the convenience of description, the semiconductor elements 30 mounted on the first element mount section 111 are referred to as “first elements 31”. As shown in FIG. 4, etc., the first element mount section 111 is offset toward one side in the second direction y (the upper side in FIG. 4) of the substrate 10. The first element mount section 111 has a band shape extending in the first direction x. In the semiconductor device A10, ten first elements 31 (semiconductor elements 30) are mounted on the first element mount section 111, but the number of first elements 31 is not limited to this. A first power supply pad 111a having a band shape extending in the second direction y is formed at one end of the first element mount section 111 in the first direction x (the right side in FIG. 4).

As shown in FIGS. 4, 9, 10 and 12, some of the semiconductor elements 30 are mounted on the second element mount section 112. For the convenience of description, the semiconductor elements 30 mounted on the second element mount section 112 are referred to as “second elements 31”. As shown in FIG. 4, etc., the second element mount section 112 is located between the first element mount section 111 and the first conductive section 113 in the second direction y. The second element mount section 112 has a band shape extending in the first direction x. In the semiconductor device A10, ten second elements 31 (semiconductor elements 30) are mounted on the second element mount section 112, but the number of second element 32 is not limited to this. An output pad 112a having a band shape extending in the second direction y is formed at one end of the second element mount section 112 in the first direction x (the left end in FIG. 4). A part of the output pad 112a that is offset from the second element mount section 112 toward one side in the second direction y (the upper side in FIG. 4) is located next to the first element mount section 111 in the first direction x. A part of the output pad 112a that is offset from the second element mount section 112 toward the other side of in the second direction y (the lower side in FIG. 4) is located next to the first conductive section 113 in the first direction x.

As shown in FIGS. 4, 9 and 10, the first conductive section 113 is electrically connected to both the first elements 31 and the second elements 32. The first conductive section 113 is located opposite to the first element mount section 111 with respect to the second element mount section 112 in the second direction y. The first conductive section 113 has a band shape extending in the first direction x. A second power supply pad 113a having a band shape extending in the second direction y is formed at one end of the first conductive section 113 in the first direction x (the right end in FIG. 4). As shown in FIG. 4, the first conductive section 113 is formed with a slit 113b extending in the first direction x. The slit 113b is located in the center of the first conductive section 113 in the second direction y and extends from one end in the first direction x (the right end in FIG. 4) to the center in the first direction x.

As shown in FIGS. 4, 9 and 10, the first gate section 114 is electrically connected to the first elements 31. The first gate section 114 has a band shape extending in the first direction x. The first gate section 114 is located between the first element mount section 111 and the case 60 in the second direction y. In the semiconductor device A10, the first gate section 114 turns back at one end in the first direction x (the right end in FIG. 4) and is formed in two rows in the second direction y. The width (the dimension in the second direction y) of the first gate section 114 is smaller than the respective widths of the first element mount section 111, the second element mount section 112 and the first conductive section 113.

As shown in FIGS. 4, 9 and 10, the first detection section 115 is electrically connected to the first elements 31. The first detection section 115 has a band shape extending in the first direction x. The first detection section 115 is located between the first element mount section 111 and the case 60 in the second direction y. In the semiconductor device A10, the first detection section 115 turns back at one end in the first direction x (the left end in FIG. 4) and is formed in two rows in the second direction y. The width (the dimension in the second direction y) of the first detection section 115 is the same as the width of the first gate section 114.

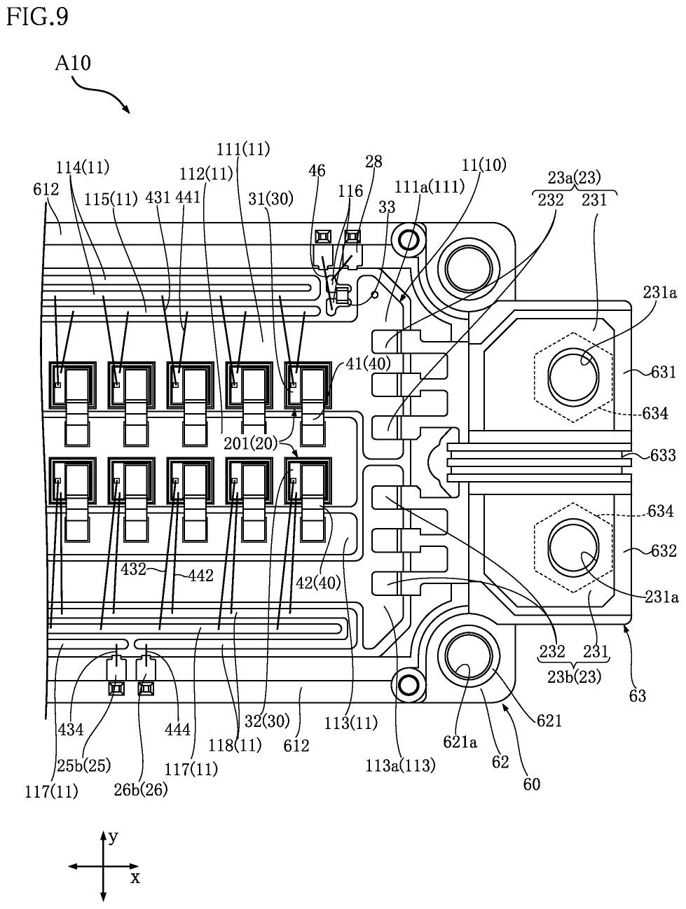

As shown in FIGS. 4 and 9, the pair of thermistor mount sections 116 are spaced apart from each other in the second direction y and carry a thermistor 33. The thermistor mount sections 116 are located close to a corner of the substrate 10. The first element mount section 111, the first gate section 114 and the first detection section 115 are located around the pair of thermistor mount sections 116.

As shown in FIGS. 4, 9 and 10, the second gate section 117 is electrically connected to the second elements 32. The second gate section 117 has a band shape extending in the first direction x. The second gate section 117 is located between the first conductive section 113 and the case 60 in the second direction y. In the semiconductor device A10, the second gate section 117 turns back at one end in the first direction x (the left end in FIG. 4) and is formed in two rows in the second direction y. The width (the dimension in the second direction y) of the second gate section 117 is smaller than the respective widths of the first element mount section 111, the second element mount section 112 and the first conductive section 113.

As shown in FIGS. 4, 9 and 10, the second detection section 118 is electrically connected to the second elements 32. The second detection section 118 has a band shape extending in the first direction x. The second detection section 118 is located between the first conductive section 113 and the case 60 in the second direction y. In the semiconductor device A10, the second detection section 118 turns back at one end in the first direction x (the right end in FIG. 4) and is formed in two rows in the second direction y. The width (the dimension in the second direction y) of the second detection section 118 is the same as the width of the second gate section 117.

As shown in FIGS. 2 to 4, etc., the power supply terminals 23 are part of external connection terminals provided in the semiconductor device A10. The power supply terminals 23 are connected to a DC power supply disposed outside the semiconductor device A10. The power supply terminals 23 are supported on the case 60. The power supply terminals 23 are formed from a metal plate. The constituent material of the metal plate is copper, for example. The power supply terminals 23 are, for example, about 1.0 mm in thickness.

The plurality of power supply terminals 23 include a first power supply terminal 23a and a second power supply terminal 23b. The first power supply terminal 23a is a positive electrode (P terminal). The first power supply terminal 23a is connected to the first power supply pad 111a of the first element mount section 111. The second power supply terminal 23b is a negative electrode (N terminal). The second power supply terminal 23b is connected to the second power supply pad 113a of the first conductive section 113. The first power supply terminal 23a and the second power supply terminal 23b are spaced apart from each other in the second direction y.

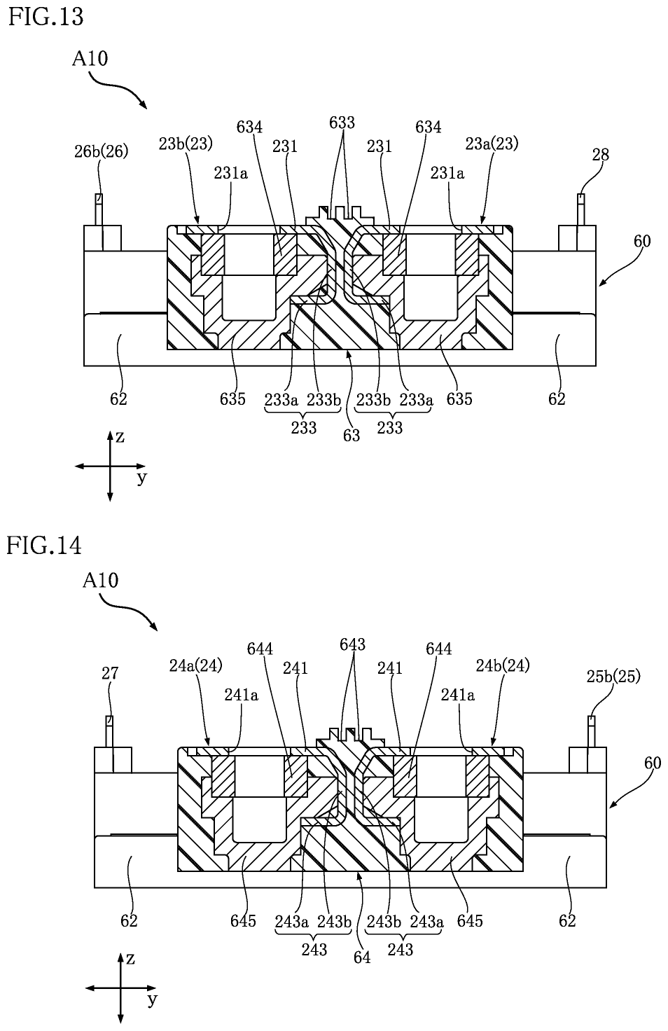

As shown in FIGS. 9 and 13, each of the first power supply terminal 23a and the second power supply terminal 23b has an external connection section 231, an internal connection section 232, and an intermediate section 233.

The external connection section 231 is a flat plate exposed from the semiconductor device A10 and orthogonal to the thickness direction z. A DC power supply cable, etc. is connected to the external connection section 231. The external connection section 231 is supported on the case 60. The external connection section 231 has a connection hole 231a penetrating in the thickness direction z. A fastening member, such as a bolt, is inserted into the connection hole 231a. The surface of the external connection section 231 may be plated with nickel (Ni).

The internal connection section 232, which has a comb shape, is connected to the first power supply pad 111a of the first element mount section 111 in the first power supply terminal 23a and connected to the second power supply pad 113a of the first conductive section 113 in the second power supply terminal 23b. In the semiconductor device A10, the internal connection section 232 has three teeth, which are arranged along the second direction y. The teeth are bent in the thickness direction z. Thus, each of the teeth has the shape of a hook as viewed in the second direction y. The teeth are connected to the first power supply pad 111a or the second power supply pad 113a by ultrasonic bonding.

The intermediate section 233 connects the external connection section 231 and the internal connection section 232 to each other. The intermediate section 233 is L-shaped in cross section with respect to the first direction x. The intermediate section 233 has a base portion 233a and a standing portion 233b. The base portion 233a is along the first direction x and the second direction y. One end of the base portion 233a in the first direction x is connected to the internal connection section 232. The standing portion 233b stands from the base portion 233a in the thickness direction z. One end of the standing portion 233b in the thickness direction z is connected to the external connection section 231.

As shown in FIGS. 2 to 4, etc., the output terminal 24 is one of external connection terminals provided in the semiconductor device A10. The output terminal 24 is connected to a power supply target (e.g., a motor) disposed outside the semiconductor device A10. The output terminal 24 is supported on the case 60 and located opposite to the power supply terminals 23 with respect to the substrate 10 in the first direction x. The output terminal 24 is formed from a metal plate. The constituent material of the metal plate is copper, for example. The output terminal 24 is 1.0 mm in thickness.

In the semiconductor device A10, the output terminal 24 is separated into two sections, i.e., a first terminal section 24a and a second terminal section 24b. Alternatively, the output terminal 24 may be a single member, not separated as in the semiconductor device A10. The first terminal section 24a and the second terminal section 24b are connected in parallel to the output pad 112a of the second element mount section 112. Thus, the output terminal 24 is connected to the second element mount section 112. The first terminal section 24a and the second terminal section 24b are spaced apart from each other in the second direction y.

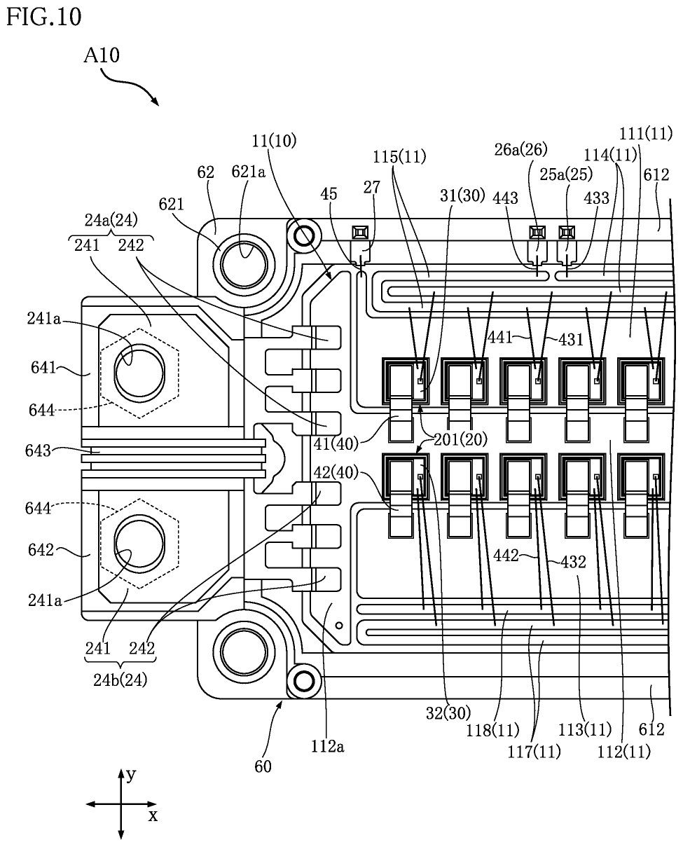

As shown in FIGS. 10 and 14, each of the first terminal section 24a and the second terminal section 24b has an external connection section 241, an internal connection section 242, and an intermediate section 243.

The external connection section 241 is a flat plate exposed from the semiconductor device A10 and orthogonal to the thickness direction z. A cable, etc. electrically connected to the power supply target is connected to the external connection section 241. The external connection section 241 is supported on the case 60. The external connection section 241 has a connection hole 241a penetrating in the thickness direction z. A fastening member, such as a bolt, is inserted into the connection hole 241a. The surface of the external connection section 241 may be plated with nickel.

The internal connection section 242, which has a comb shape, is connected to the output pad 112a of the second element mount section 112. In the semiconductor device A10, the internal connection section 242 has three teeth, which are arranged along the second direction y. The teeth are bent in the thickness direction z. Thus, each of the teeth has the shape of a hook as viewed in the second direction y. The teeth are connected to the output pad 112a by ultrasonic bonding.

The intermediate section 243 connects the external connection section 241 and the internal connection section 242 to each other. The intermediate section 243 is L-shaped in cross section with respect to the first direction x. The intermediate section 243 has a base portion 243a and a standing portion 243b. The base portion 243a is along the first direction x and the second direction y. One end of the base portion 243a in the first direction x is connected to the internal connection section 242. The standing portion 243b stands from the base portion 243a in the thickness direction z. One end of the standing portion 243b in the thickness direction z is connected to the external connection section 241.

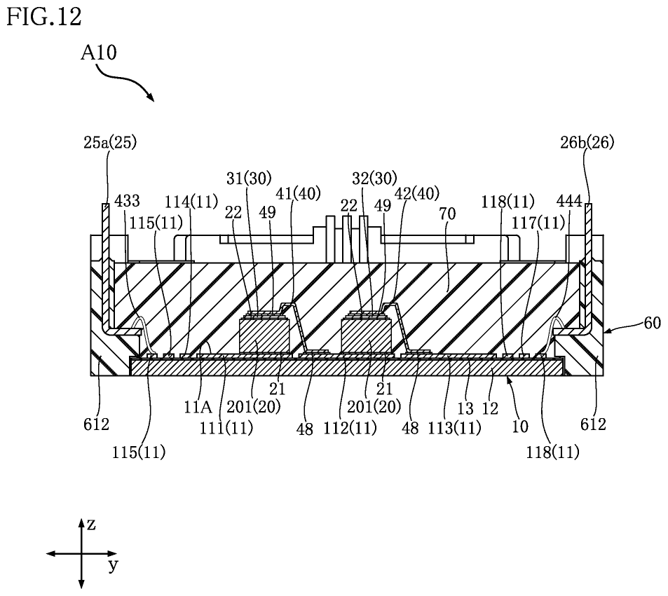

As shown in FIGS. 2 to 5, etc., the gate terminals 25 are part of external connection terminals provided in the semiconductor device A10. Each of the gate terminals 25 is electrically connected to the first gate section 114 or the second gate section 117. The gate terminals 25 are connected to a drive circuit (e.g., a gate driver) of the semiconductor device A10 disposed outside. The gate terminals 25 are supported on the case 60. The gate terminals 25 are formed from metal rods. The constituent material of the metal rods is copper, for example. The surfaces of the gate terminals 25 may be plated with tin (Sn) or plated with nickel and tin. As shown in FIG. 12, the gate terminals 25 are L-shaped in cross section with respect to the first direction x. Each of the gate terminals 25 partially protrudes from the case 60 toward the side which the obverse surface 11A of the first metal layer 11 (the substrate 10) faces in the thickness direction z.

The plurality of gate terminals 25 include a first gate terminal 25a and a second gate terminal 25b. As shown in FIG. 10, the first gate terminal 25a is located close to the first gate section 114 in the second direction y. As shown in FIG. 9, the second gate terminal 25b is located opposite to the first gate terminal 25a with respect to the first metal layer 11 (the substrate 10) in the second direction y. The second gate terminal 25b is located close to the second gate section 117.

As shown in FIGS. 2 to 5, etc., the element current detection terminals 26 are part of external connection terminals provided in the semiconductor device A10. Each of the element current detection terminals 26 is electrically connected to the first detection section 115 or the second detection section 118. The element current detection terminals 26 are connected to a control circuit of the semiconductor device A10 disposed outside. The element current detection terminals 26 are supported on the case 60. The element current detection terminals 26 are formed from metal rods. The constituent material of the metal rods is copper, for example. The surfaces of the element current detection terminals 26 may be plated with tin or plated with nickel and tin. As shown in FIG. 12, the element current detection terminals 26 are L-shaped in cross section with respect to the first direction x. Each of the element current detection terminals 26 partially protrudes from the case 60 toward the side which the obverse surface 11A of the first metal layer 11 (the substrate 10) faces in the thickness direction z.

The plurality of element current detection terminals 26 include a first detection terminal 26a and a second detection terminal 26b. As shown in FIG. 10, the first detection terminal 26a is located next to the first gate terminal 25a in the first direction x. As shown in FIG. 9, the second detection terminal 26b is located next to the second gate terminal 25b in the first direction x.

As shown in FIGS. 2 to 5 and 10, the semiconductor device A10 includes a power supply current detection terminal 27. The power supply current detection terminal 27 is one of external connection terminals provided in the semiconductor device A10. The power supply current detection terminal 27 is connected to a control circuit of the semiconductor device A10 disposed outside. The power supply current detection terminal 27 is supported on the case 60. The power supply current detection terminal 27 is formed from a metal rod. The constituent material of the metal rod is copper, for example. The surface of the power supply current detection terminal 27 may be plated with tin or plated with nickel and tin. The shape of the power supply current detection terminal 27 is the same as that of the gate terminals 25 shown in FIG. 12. As with the gate terminals 25 shown in FIG. 12, the power supply current detection terminal 27 partially protrudes from the case 60 toward the side which the obverse surface 11A of the first metal layer 11 (the substrate 10) faces in the thickness direction z. In the second direction y, the position of the power supply current detection terminal 27 is the same as the position of the first gate terminal 25a. The power supply current detection terminal 27 is spaced apart from the first gate terminal 25a toward the first terminal section 24a (the output terminal 24) in the first direction x.

As shown in FIG. 10, the semiconductor device A10 includes a power supply current detection wire 45. The power supply current detection wire 45 is a conductive member and connected to the power supply current detection terminal 27 and the first element mount section 111. Thus, the power supply current detection terminal 27 is electrically connected to the first element mount section 111. The constituent material of the power supply current detection wire 45 is aluminum, for example.

As shown in FIGS. 2 to 5 and 9, the semiconductor device A10 includes a pair of thermistor terminals 28. The thermistor terminals 28 are part of external connection terminals provided in the semiconductor device A10. The thermistor terminals 28 are connected to a control circuit of the semiconductor device A10 disposed outside. The thermistor terminals 28 are supported on the case 60. The thermistor terminals 28 are formed from metal rods. The constituent material of the metal rods is copper, for example. The surfaces of the thermistor terminals 28 may be plated with tin or plated with nickel and tin. The shape of the thermistor terminals 28 is the same as that of the gate terminals 25 shown in FIG. 12. As with the gate terminals 25 shown in FIG. 12, each of the thermistor terminals 28 partially protrudes from the case 60 toward the side which the obverse surface 11A of the first metal layer 11 (the substrate 10) faces in the thickness direction z. In the second direction y, the position of the thermistor terminals 28 is the same as the position of the first gate terminal 25a. The thermistor terminals 28 are spaced apart from the first gate terminal 25a toward the first power supply terminal 23a in the first direction x. The thermistor terminals 28 are spaced apart from each other in the first direction x.

As shown in FIG. 9, the semiconductor device A10 includes a pair of thermistor wires 46. The thermistor wires 46 are conductive members and individually connected to the thermistor terminals 28 and the thermistor mount sections 116. Thus, the thermistor terminals 28 are electrically connected to the thermistor mount sections 116. The constituent material of the thermistor wires 46 is aluminum, for example.

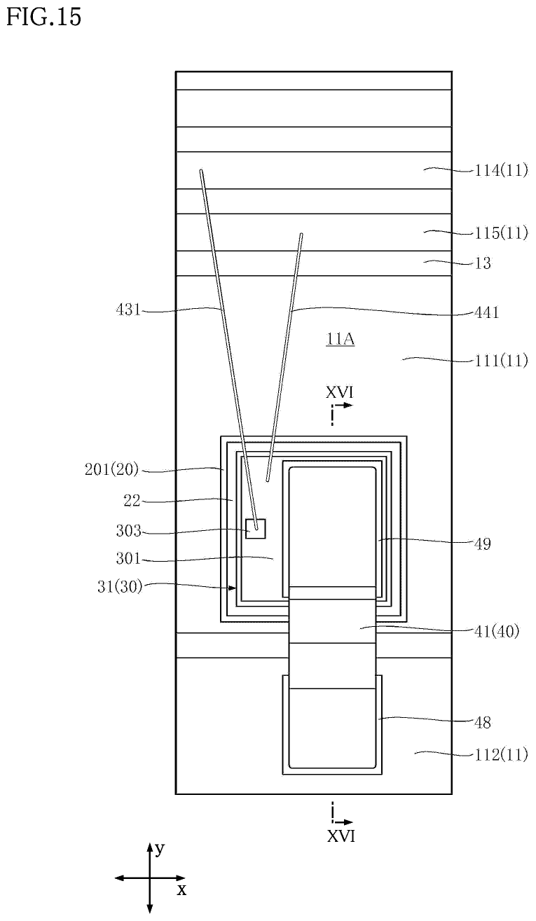

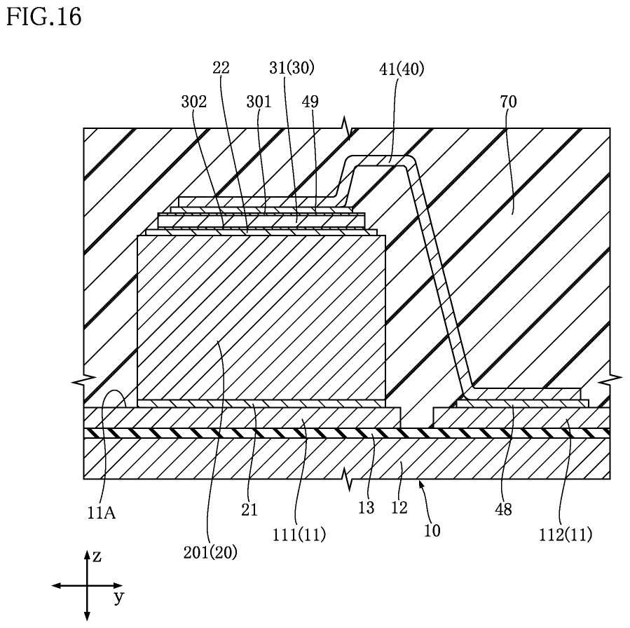

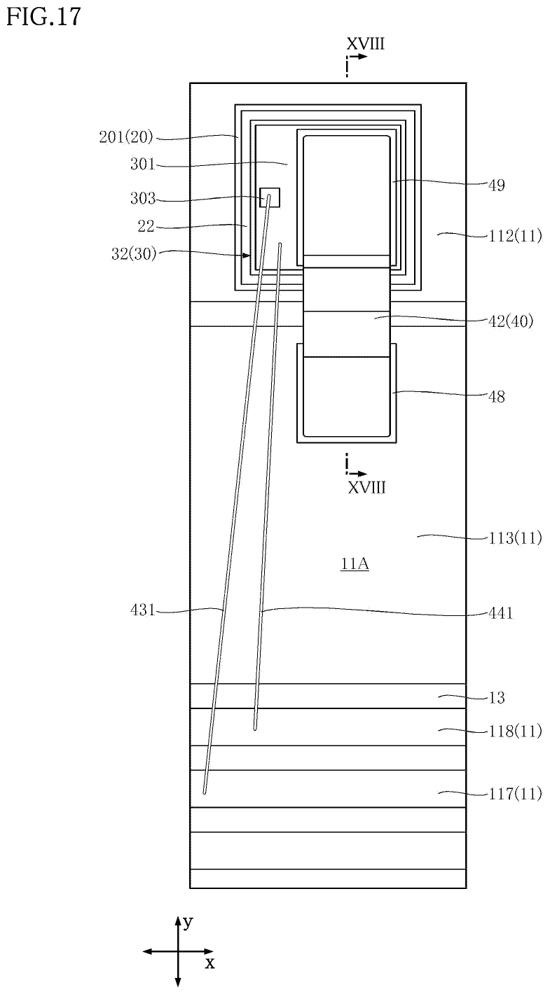

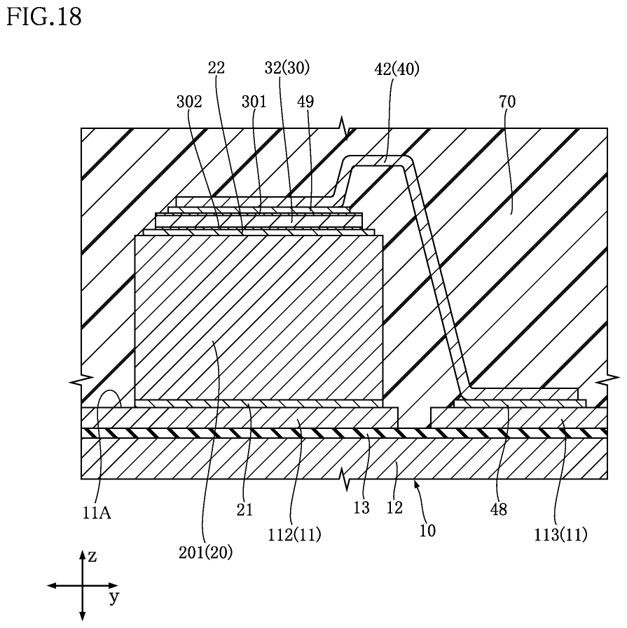

Each of the semiconductor elements 30 (the first elements 31 and the second elements 32) has a semiconductor layer containing silicon carbide (SiC), for example, and has a switching function. The semiconductor elements 30 are MOSFETs (Metal-Oxide-Semiconductor Field-Effect Transistor) made by using a semiconductor material mainly composed of silicon carbide. The semiconductor elements 30 are not limited to MOSFETs and may be IGBTs (Insulated Gate Bipolar Transistor). For the semiconductor device A10, an example in which the semiconductor elements 30 are MOSFETs is described. As shown in FIGS. 15 and 17, each of the semiconductor elements 30 is rectangular (square in the semiconductor device A10) as viewed in the thickness direction z. In the semiconductor device A10, the thickness of each semiconductor element 30 is, for example, 400 μm or less, and more preferably, 150 μm or less.

As shown in FIGS. 15 to 18, each of the semiconductor elements 30 has a source electrode 301, a drain electrode 302, and a gate electrode 303. The source electrode 301 is provided at the upper end of the semiconductor element 30 that faces in the same sense of the thickness direction z as the obverse surface 11A of the first metal layer 11 (the substrate 10). Source current flows from inside the semiconductor element 30 to the source electrode 301.

The drain electrode 302 is provided at the lower end of the semiconductor element 30 that faces in the opposite sense of the thickness direction z from the obverse surface 11A of the first metal layer 11 (the substrate 10). Drain current flows from inside of the semiconductor element 30 to the drain electrode 302.

The gate electrode 303 is provided at the upper end of the semiconductor element 30 that faces in the same sense of the thickness direction z as the obverse surface 11A of the first metal layer 11 (the substrate 10). Gate voltage for driving the semiconductor elements 30 is applied to the gate electrode 303. As viewed in the thickness direction z, the area of the gate electrode 303 is smaller than the area of the source electrode 301.

The plurality of semiconductor elements 30 include a plurality of first elements 31 and a plurality of second elements 32. The first elements 31 are mounted on the first element mount section 111. The first elements 31 are arranged at predetermined intervals in the first direction x. The second elements 32 are mounted on the second element mount section 112. The second element 32 are arranged at predetermined intervals in the first direction x.

As shown in FIGS. 11, 12, and 15 to 18, the first layer 20 is located between the obverse surface 11A of the first metal layer 11 (the first element mount section 111 and the second element mount section 112) and the semiconductor elements 30 in the thickness direction z. The first layer 20 is made of a metal material having electrical conductivity. The first layer 20 is made of a material having the same thermal conductivity as the second metal layer 12 or a material having a greater thermal conductivity than the second metal layer 12. The first layer 20 is made of copper or a copper alloy, for example. When the constituent material of the first layer 20 is copper, the thermal conductivity of the first layer 20 is 398 W/mk. Examples of the constituent material of the first layer 20 include aluminum, iron, and carbon, in addition to copper and a copper alloy. The thickness of the first layer 20 is larger than that of the second metal layer 12. Preferably, the thickness of the first layer 20 is one to ten times the thickness of the second metal layer 12. The thickness of the first layer 20 is, for example, 1 mm to 4 mm, and preferably, 2 mm to 3 mm.

In the semiconductor device A10, the first layer 20 includes a plurality of individual sections 201 separated from each other. In the semiconductor device A10, the plurality of individual sections 201 are disposed individually for the plurality of semiconductor elements 30. Each of the semiconductor elements 30 is supported on one of the individual sections 201. In the semiconductor device A10, the individual sections 201 corresponding to the first elements 31 are supported on the first element mount section 111 and arranged at predetermined intervals in the first direction x. The individual sections 201 corresponding to the second elements 32 are supported on the second element mount section 112 and arranged at predetermined intervals in the first direction x. The individual sections 201 are larger than the semiconductor elements 30 as viewed in the thickness direction z. The individual sections 201 are rectangular (square in the semiconductor device A10) as viewed in the thickness direction z.

The second layer 21 is located between the first metal layer 11 (the first element mount section 111 and the second element mount section 112) and the first layer 20 (the individual sections 201) in the thickness direction z. The second layer 21 has electrical conductivity and conductively bonds the respective obverse surfaces 11A of the first element mount section 111 and the second element mount section 112 to the individual sections 201. The constituent material of the second layer 21 is, for example, lead-free solder containing tin as the main component. The thickness of the second layer 21 is 0.02 mm to 0.20 mm, for example.

In the semiconductor device A10, the second layer 21 includes a plurality of regions separated from each other. The plurality of regions of the second layer 21 individually correspond to the plurality of individual sections 201. The second layer 21 may include a region common to some of the individual sections 201. For example, the second layer 21 may be configured to include a region common to the individual sections 201 supported on the first element mount section 111 and a region common to the individual sections 201 supported on the second element mount section 112.

The third layer 22 is located between the first layer 20 (the individual sections 201) and the semiconductor elements 30 in the thickness direction z. The third layer 22 has electrical conductivity and conductively bonds the individual sections 201 and the semiconductor elements 30 to each other. More specifically, the drain electrode 302 of each semiconductor element 30 and the first layer 20 (individual section 201) are conductively bonded to each other by the third layer 22. The third layer 22 is made of a bonding material containing a metal material. In the semiconductor device A10, the constituent material of the third layer 22 includes silver. In the semiconductor device A10, the third layer 22 is sintered silver. Alternatively, the third layer 22 may be composed of sintered metal containing metals other than silver (e.g., sintered copper), aluminum subjected to solid-phase diffusion bonding, solder, or metal paste material. The thickness of the third layer 22 is 0.02 mm to 0.20 mm, for example.

As shown in FIGS. 12 and 15 to 18, etc., the conductive members 40 are bonded to the source electrodes 301 of the semiconductor elements 30 and the second element mount section 112 or the first conductive section 113. The conductive members are formed from metal plates. The metal may be copper or a copper alloy. The conductive members 40 are formed by bending the metal plates.

The plurality of conductive members 40 include a plurality of first conductive members 41 and a plurality of second conductive members 42. Each of the first conductive members 41 is bonded to the source electrode 301 of one of the first elements 31 and the second element mount section 112. The first conductive members 41 and the second element mount section 112 are bonded to each other via conductive member bonding layers 48. The first conductive members 41 and the source electrodes 301 of the first elements 31 are bonded to each other via conductive member bonding layers 49. The conductive member bonding layers 48 and the conductive member bonding layers 49 bonded to the first conductive members 41 are solder, metal paste, or sintered metal, for example.

Each of the second conductive members 42 is bonded to the source electrode 301 of one of the second elements 32 and the first conductive section 113. The second conductive members 42 and the first conductive section 113 are bonded to each other via conductive member bonding layers 48. The second conductive members 42 and the source electrodes 301 of the second elements 32 are bonded to each other via conductive member bonding layers 49. The conductive member bonding layers 48 and the conductive member bonding layers 49 bonded to the second conductive member 42 are solder, metal paste, or sintered metal, for example.

As shown in FIGS. 4 and 9, the semiconductor device A10 includes the thermistor 33. The thermistor 33 is electrically bonded to the pair of thermistor mount sections 116. In the semiconductor device A10, the thermistor 33 is an NTC (Negative Temperature Coefficient) thermistor. NTC thermistors have the characteristic that their resistance gradually decreases as the temperature rises. The thermistor 33 is used as a temperature detection sensor of the semiconductor device A10. The thermistor 33 is electrically connected to the pair of thermistor terminals 28 via the pair of thermistor mount sections 116 and the pair of thermistor wires 46.

As shown in FIGS. 9, 10, 15 and 17, the semiconductor device A10 includes a plurality of first gate wires 431, a plurality of second gate wires 432, a third gate wire 433, and a fourth gate wire 434. Each of the first gate wires 431 is a conductive member having one end connected to the gate electrode 303 of one of the first elements 31 and another end connected to the first gate section 114. Each of the second gate wires 432 is a conductive member having one end connected to the gate electrode 303 of one of the second elements 32 and another end connected to the second gate section 117. The constituent material of the first gate wires 431 and the second gate wires 432 is aluminum, for example.

The third gate wire 433 is a conductive member and connected to the first gate terminal 25a and the first gate section 114. Thus, the first gate terminal 25a is electrically connected to the gate electrodes 303 of the first elements 31 mounted on the first element mount section 111. The fourth gate wire 434 is a conductive member and connected to the second gate terminal 25b and the second gate section 117. Thus, the second gate terminal 25b is electrically connected to the gate electrodes 303 of the second elements 32 mounted on the second element mount section 112. The constituent material of the third gate wire 433 and the fourth gate wire 434 is aluminum, for example.

As shown in FIGS. 9, 10, 15 and 17, the semiconductor device A10 includes a plurality of first detection wires 441, a plurality of second detection wires 442, a third detection wire 443, and a fourth detection wire 444. Each of the first detection wires 441 is a conductive member having one end connected to the source electrode 301 of one of the first elements 31 and another end connected to the first detection section 115. Each of the second detection wires 442 is a conductive member having one end connected to the source electrode 301 of one of the second elements 32 and another end connected to the second detection section 118. The constituent material of the first detection wires 441 and the second detection wires 442 is aluminum, for example.

The third detection wire 443 is a conductive member and connected to the first detection terminal 26a and the first detection section 115. Thus, the first detection terminal 26a is electrically connected to the source electrodes 301 of the first elements 31 mounted on the first element mount section 111. The fourth detection wire 444 is a conductive member and connected to the second detection terminal 26b and the second detection section 118. Thus, the second detection terminal 26b is electrically connected to the source electrodes 301 of the second elements 32 mounted on the second element mount section 112. The constituent material of the third detection wire 443 and the fourth detection wire 444 is aluminum, for example.

As shown in FIGS. 3 to 7, the case 60 is an electrically insulating member surrounding the first metal layer 11 (the substrate 10) as viewed in the thickness direction z. The constituent material of the case 60 is a synthetic resin with excellent heat resistance, such as PPS (polyphenylene sulfide). The case 60 includes a pair of first side walls 611, a pair of second side walls 612, a plurality of mount portions 62, a power supply terminal base 63 and an output terminal base 64.

As shown in FIGS. 2 and 4, the pair of first side walls 611 are spaced apart from each other in the first direction x. The pair of first side walls 611 are disposed along the second direction y and the thickness direction z.

As shown in FIGS. 2 and 4, the pair of second side walls 612 are spaced apart from each other in the second direction y. The second side walls 612 are disposed along the first direction x and the thickness direction z. The opposite ends of each of the second side walls 612 in the first direction x are connected to the first side walls 611. The first gate terminal 25a, the first detection terminal 26a, the power supply current detection terminal 27 and the pair of thermistor terminals 28 are disposed on the inner side of one of the second side walls 612. The second gate terminal 25b and the second detection terminal 26b are disposed on the inner side of the other second side wall 612. As shown in FIGS. 9, 10 and 12, the ends of these terminals that are closer to the first metal layer 11 (the substrate 10) in the thickness direction z are supported on the pair of second side walls 612.

As shown in FIGS. 2, 9 and 10, the mount portions 62 are provided at four corners of the case 60 as viewed in the thickness direction z. Each of the mount portions 62 is formed with a through-hole penetrating in the thickness direction z, and a mounting member 621 is fitted in each of the through-holes. Each of the mounting members 621 has a mounting hole 621a penetrating in the thickness direction z. Fitting a fastening member, not shown, into each mounting hole 621a allows a heat dissipation member (e.g., a heat sink), not shown, to be attached to the semiconductor device A10.

As shown in FIGS. 2, 6 and 9, the power supply terminal base 63 protrudes outward in the first direction x from one of the first side walls 611. The power supply terminal base 63 supports the power supply terminals 23. The power supply terminal base 63 includes a first terminal base 631 and a second terminal base 632. The first terminal base 631 and the second terminal base 632 are spaced apart from each other in the second direction y. The first terminal base 631 supports the first power supply terminal 23a. The external connection section 231 of the first power supply terminal 23a is exposed from the first terminal base 631. The second terminal base 632 supports the second power supply terminal 23b. The external connection section 231 of the second power supply terminal 23b is exposed from the second terminal base 632. A plurality of grooves 633 extending in the first direction x are formed between the first terminal base 631 and the second terminal base 632. As shown in FIGS. 9 and 13, a pair of nuts 634 and a pair of intermediate members 635 are disposed inside the first terminal base 631 and the second terminal base 632. Each intermediate member 635 is located on the second side in the thickness direction z (the lower side in FIG. 13) with respect to a nut 634 and held in contact with the nut 634. One of the nuts 634 and the relevant intermediate member 635 are held in engagement with the external connection section 231 and the intermediate section 233 of the first power supply terminal 23a. The other nut 634 and the relevant intermediate member 635 are held in engagement with the external connection section 231 and the intermediate section 233 of the second power supply terminal 23b. Each of the intermediate members 635 is partially exposed from the power supply terminal base 63. The pair of nuts 634 correspond to the pair of connection holes 231a provided in the first power supply terminal 23a and the second power supply terminal 23b. Fastening members such as bolts inserted in the connection holes 231a mesh with the nuts 634.

As shown in FIGS. 2, 7 and 10, the output terminal base 64 protrudes outward in the first direction x from the other first side wall 611. The output terminal base 64 supports the output terminal 24. The output terminal base 64 includes a first terminal base 641 and a second terminal base 642. The first terminal base 641 and the second terminal base 642 are spaced apart from each other in the second direction y. The first terminal base 641 supports the first terminal section 24a of the output terminal 24. The external connection section 241 of the first terminal section 24a is exposed from the first terminal base 641. The second terminal base 642 supports the second terminal section 24b of the output terminal 24. The external connection section 241 of the second terminal section 24b is exposed from the second terminal base 642. A plurality of grooves 643 extending in the first direction x are formed between the first terminal base 641 and the second terminal base 642. As shown in FIGS. 10 and 14, a pair of nuts 644 and a pair of intermediate members 645 are disposed inside the first terminal base 641 and the second terminal base 642. Each intermediate member 645 is located on the second side in the thickness direction z (the lower side in FIG. 14) with respect to a nut 644 and held in contact with the nut 644. One of the nuts 644 and the relevant intermediate member 645 are held in engagement with the external connection section 241 and the intermediate section 243 of the first terminal section 24a. The other nut 644 and the relevant intermediate member 645 are held in engagement with the external connection section 241 and the intermediate section 243 of the second terminal section 24b. Each of the intermediate members 645 is partially exposed from the output terminal base 64. The pair of nuts 644 correspond to the pair of connection holes 241a provided in the first terminal section 24a and the second terminal section 24b. Fastening members such as bolts inserted in the connection holes 241a mesh with the nuts 644.

As shown in FIGS. 11 and 12, the sealing resin 70 is contained in the area enclosed by the case 60 and the substrate 10. The sealing resin 70 covers the semiconductor elements 30. The constituent material of the sealing resin 70 is black epoxy resin, for example. Other materials, such as silicone gel, may be selected as the constituent material of the sealing resin 70.

In the semiconductor device A10, two switching circuits, i.e., an upper arm circuit and a lower arm circuit are formed. The upper arm circuit is constituted of the first element mount section 111 and the first elements 31 mounted on the first element mount section 111. The first elements 31 mounted on the first element mount section 111 are connected in parallel between the first power supply terminal 23a and the output terminal 24. The gate electrodes 303 of the first elements 31 in the upper arm circuit are all connected in parallel to the first gate terminal 25a. When a gate voltage is applied to the first gate terminal 25a by a drive circuit such as a gate driver disposed outside the semiconductor device A10, the first elements 31 in the upper arm circuit are driven simultaneously. The source electrodes 301 of the first elements 31 in the upper arm circuit are all connected in parallel to the first detection terminal 26a. The source current flowing in the first elements 31 in the upper arm circuit is inputted to the control circuit of the semiconductor device A10 disposed outside the semiconductor device A10.

The lower arm circuit is constituted of the second element mount section 112 and the second element 32 mounted on the second element mount section 112. The second elements 32 mounted on the second element mount section 112 are connected in parallel between the output terminal 24 and the second power supply terminal 23b. The gate electrodes 303 of the second elements 32 in the lower arm circuit are all connected in parallel to the second gate terminal 25b. When a gate voltage is applied to the second gate terminal 25b by a drive circuit such as a gate driver disposed outside the semiconductor device A10, the second elements 32 in the lower arm circuit are driven simultaneously. The source electrodes 301 of the second elements 32 in the lower arm circuit are all connected in parallel to the second detection terminal 26b. The source current flowing in the second elements 32 in the lower arm circuit is inputted to the control circuit of the semiconductor device A10 disposed outside the semiconductor device A10.

When a DC power supply is connected to the first power supply terminal 23a and the second power supply terminal 23b and the semiconductor elements 30 (the first elements 31 and the second elements 32) in the upper arm circuit and the lower arm circuit are driven, AC voltages of various frequencies are output from the output terminal 24. The AC voltages outputted from the output terminal 24 are supplied to a power supply target, such as a motor.

The advantages of the semiconductor device A10 are described below.

The semiconductor device A10 includes the first layer 20, the second layer 21, and the third layer 22. The first layer 20 is located between the obverse surface 11A of the first metal layer 11 (the first element mount section 111 and the second element mount section 112) and the semiconductor elements 30 and has electrical conductivity. The second layer 21 conductively bonds the obverse surface 11A of the first metal layer 11 (the first element mount section 111 and the second element mount section 112) and the semiconductor elements 30 to each other. The third layer 22 conductively bonds the first layer 20 and the semiconductor elements 30. Such a configuration including the first layer 20 can increase the heat capacity of the portion between the semiconductor elements 30 and the substrate 10, preventing the heat saturation of the portion. The heat generated at each semiconductor element 30 diffuses in the first layer 20 and is quickly dissipated toward the first metal layer 11 (the substrate 10). Thus, the semiconductor device A10 is capable of efficiently dissipating the heat generated at the semiconductor elements 30. The semiconductor device A10 is thus capable of suppressing the temperature rise around the semiconductor elements 30 and suitable for passing a large current.

The substrate 10 on which the semiconductor elements 30 are mounted includes the first metal layer 11, the second metal layer 12, and the insulating layer 13. The first metal layer 11 includes the obverse surface 11A facing the first side in the thickness direction z. The second metal layer 12 is located on the second side in the thickness direction z with respect to the first metal layer 11. The insulating layer 13 is located between the first metal layer 11 and the second metal layer 12. The substrate 10 is constituted of the second metal layer 12, the insulating layer 13 and the first metal layer 11 deposited in this order. The first metal layer 11 (the first element mount section 111 and the second element mount section 112) functions as a circuit layer on which the semiconductor elements 30 are mounted and has a relatively small thickness. In the semiconductor device A10, the heat generated at the semiconductor elements 30 can be quickly dissipated in the first layer 20 located between the semiconductor elements 30 and the first metal layer 11. Thus, the heat from the semiconductor elements 30 is prevented from being retained in the first metal layer 11 deposited on the insulating layer 13.

The first layer 20 includes a plurality of individual sections 201 separated from each other. Each of the semiconductor elements 30 is supported on one of the individual sections 201. With such a configuration, the heat generated at the semiconductor elements 30 does not interfere with each other.

The constituent material of the first layer 20 includes copper. The thickness of the first layer 20 is larger than that of the second metal layer 12. Such a configuration can enhance thermal conductivity and heat dissipation in the first layer 20. As a preferable example, the thickness of the first layer 20 is 2 mm to 3 mm and one to ten times the thickness of the second metal layer 12. Such a configuration further enhances the heat dissipation in the first layer 20.

The constituent material of the third layer 22 includes silver. The third layer 22 is sintered silver (sintered metal). Therefore, the third layer 22 has excellent thermal conductivity. Thus, the heat generated at the semiconductor elements 30 is quickly transferred to the second layer 21 via the third layer 22. This is favorable for efficient dissipation of the heat generated at the semiconductor elements 30.

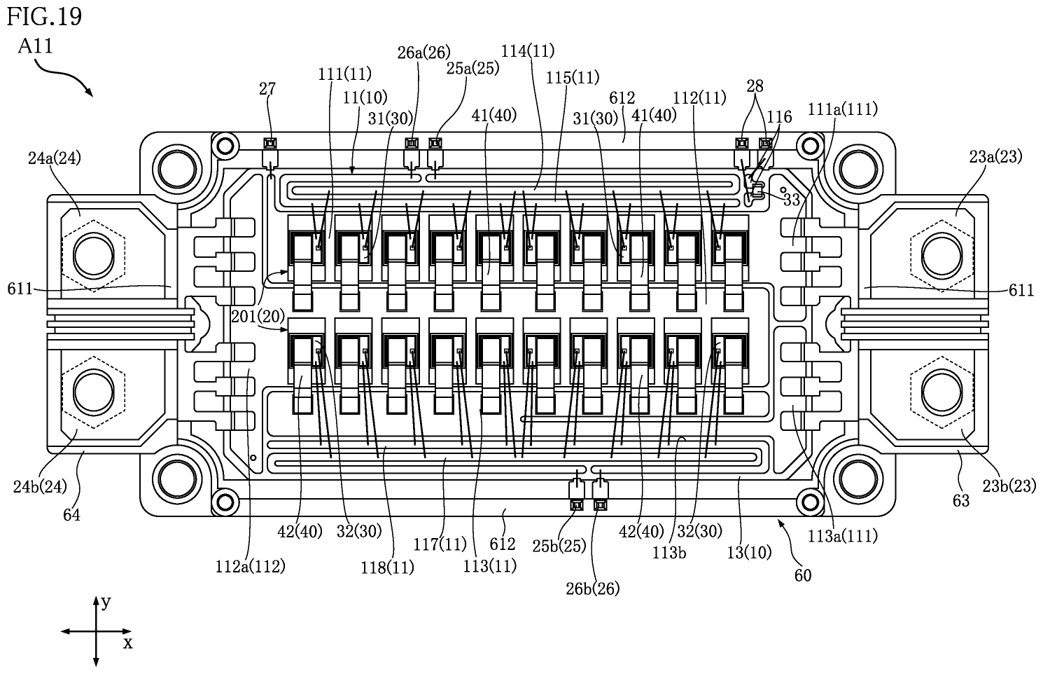

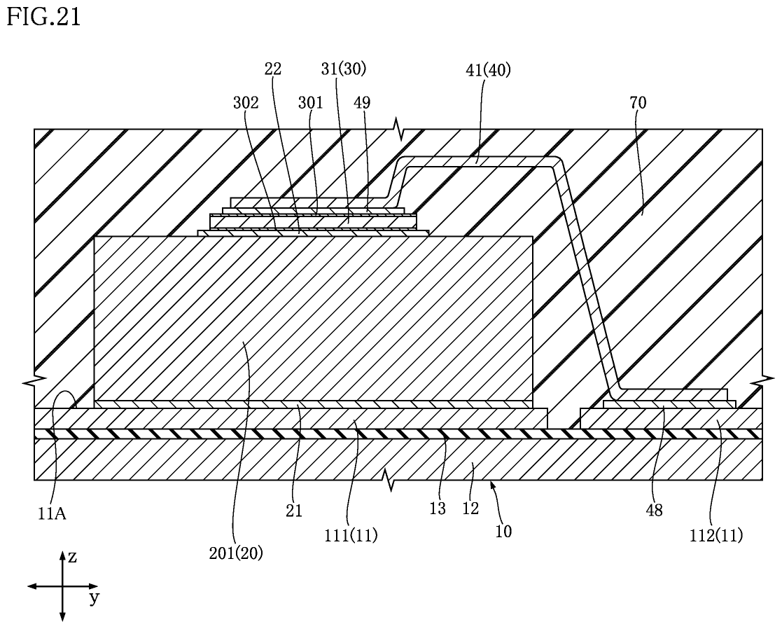

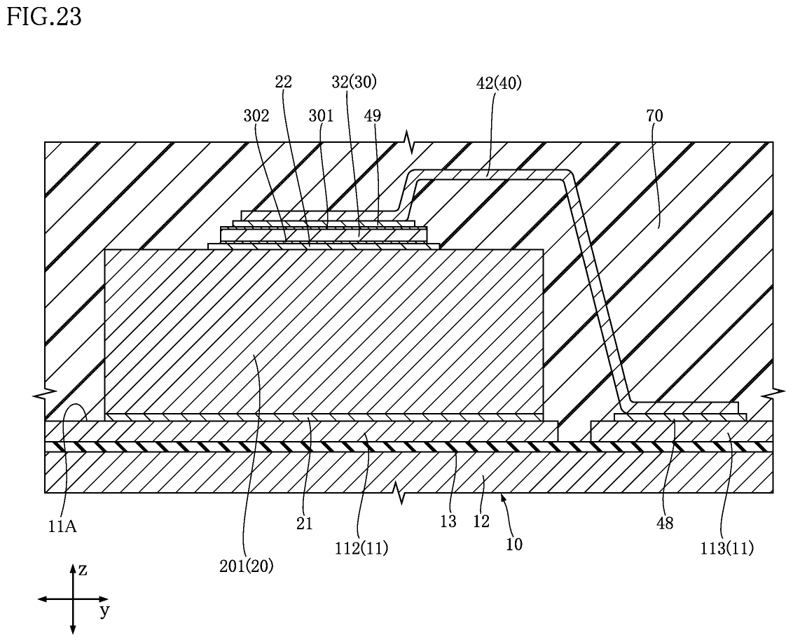

FIGS. 19 to 23 show a semiconductor device according to a variation of the first embodiment. In FIG. 19 and the subsequent figures, the elements that are identical or similar to those of the semiconductor device A10 of the foregoing embodiment are denoted by the same reference signs as those used for the foregoing embodiment, and the description thereof is omitted.

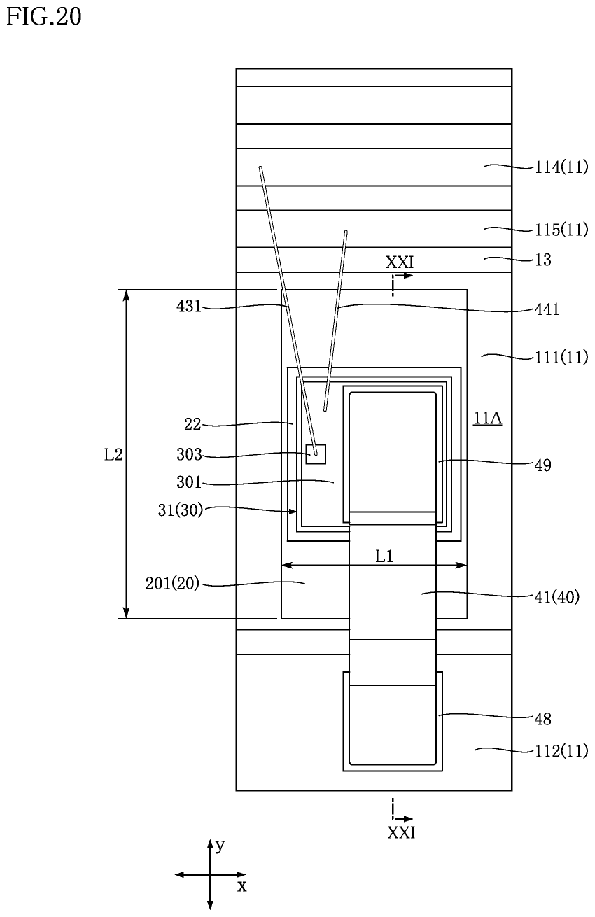

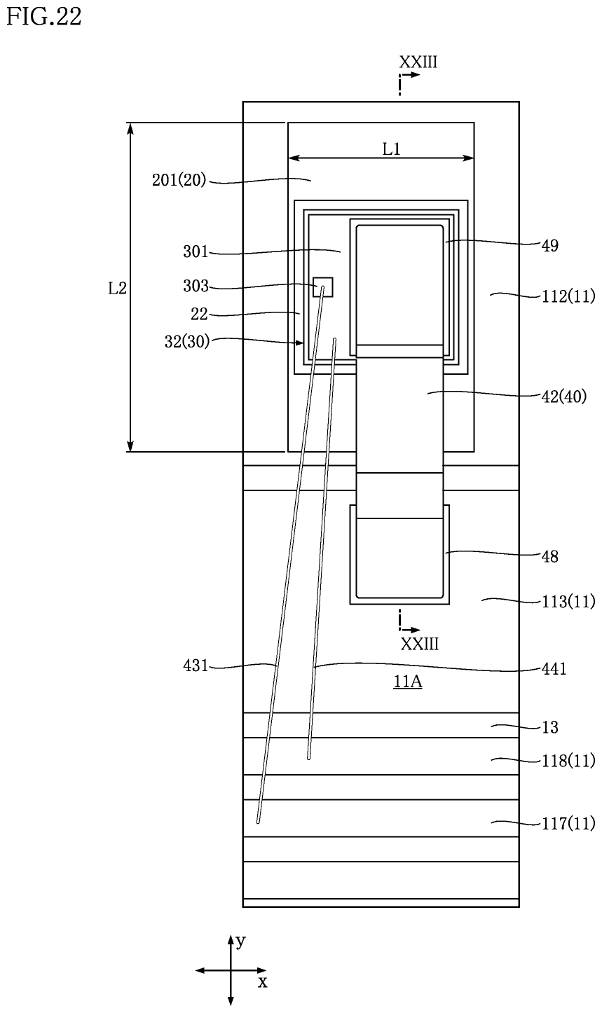

The semiconductor device A11 of the present variation differs from the semiconductor device A10 of the foregoing embodiment mainly in configuration of the first layer 20. In the present variation, each of the individual sections 201 forming the first layer 20 is made larger in dimension in the second direction y as compared with the foregoing embodiment and has an elongated rectangular shape as viewed in the thickness direction. As shown in FIGS. 20 and 22, in each of the individual sections 201, the dimension L2 in the second direction y is larger than the dimension L1 in the first direction x. In the illustrated example, the dimension L2 in the second direction y of each individual section 201 is larger than the dimension L1 in the first direction x. However, the dimension L2 is not necessarily larger than the dimension L1. The dimension L1 and the dimension L2 are limited by the package size of the semiconductor device A11. To efficiently diffuse the heat from the semiconductor elements 30 in the first layer 20, it is desirable that both the dimension L1 in the first direction x and the dimension L2 in the second direction y are large relative to the size in plan view of each semiconductor element 30 within the range limited by the package size. As an example, the dimension L2 in the second direction y of each individual section 201 is 0.5 to 2.0 times the dimension L1 in the first direction x of the individual section 201. The dimension L2 in the second direction y of each individual section 201 is 1.2 to 4.0 times the dimension in the second direction y of each semiconductor element 30.

The semiconductor device A11 of the present variation has the same effect as the semiconductor device A10 of the foregoing embodiment. In the present variation, in each of the individual sections 201, the dimension L2 in the second direction y is larger than the dimension L1 in the first direction x, which is the arrangement direction of the semiconductor elements 30. Such a configuration can increase the volume of the first layer 20 (the plurality of individual sections 201) and hence increase the heat capacity of the first layer 20. Thus, the heat generated at the semiconductor elements 30 can be diffused in the individual sections 201 in the second direction y and efficiently dissipated.

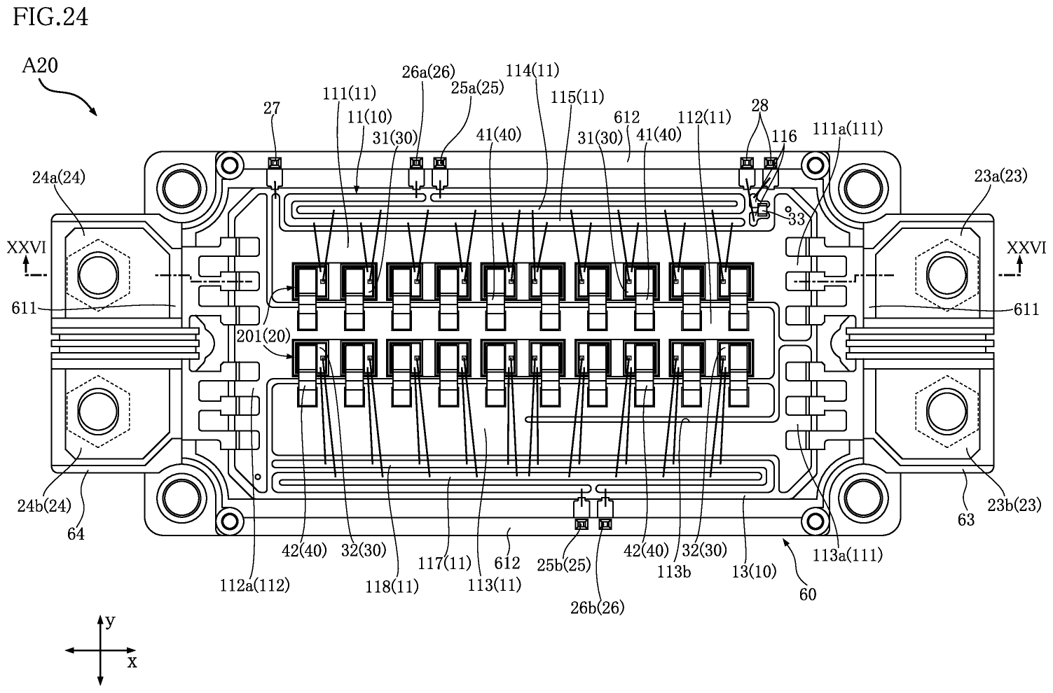

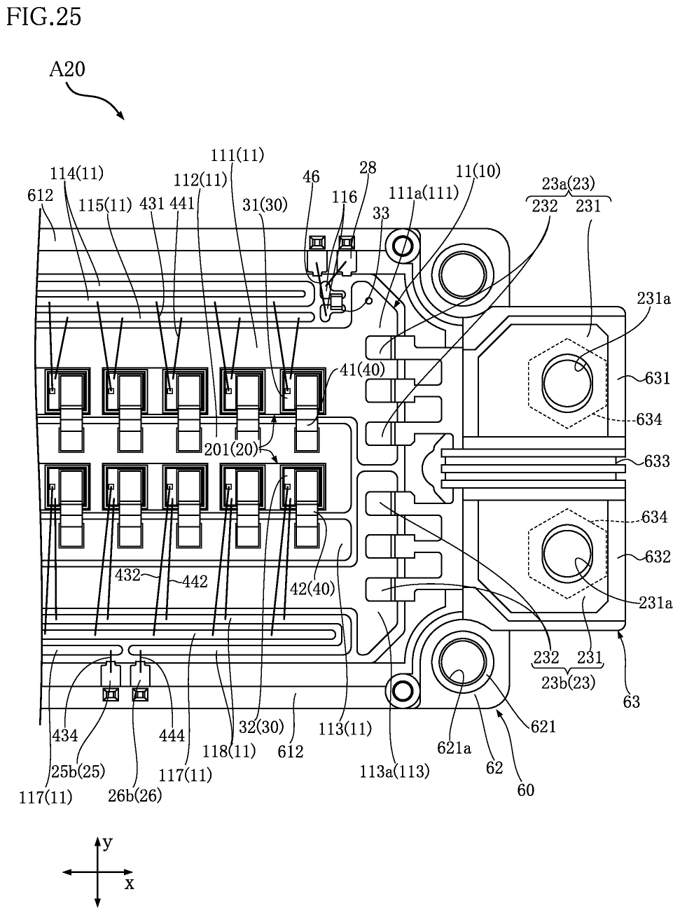

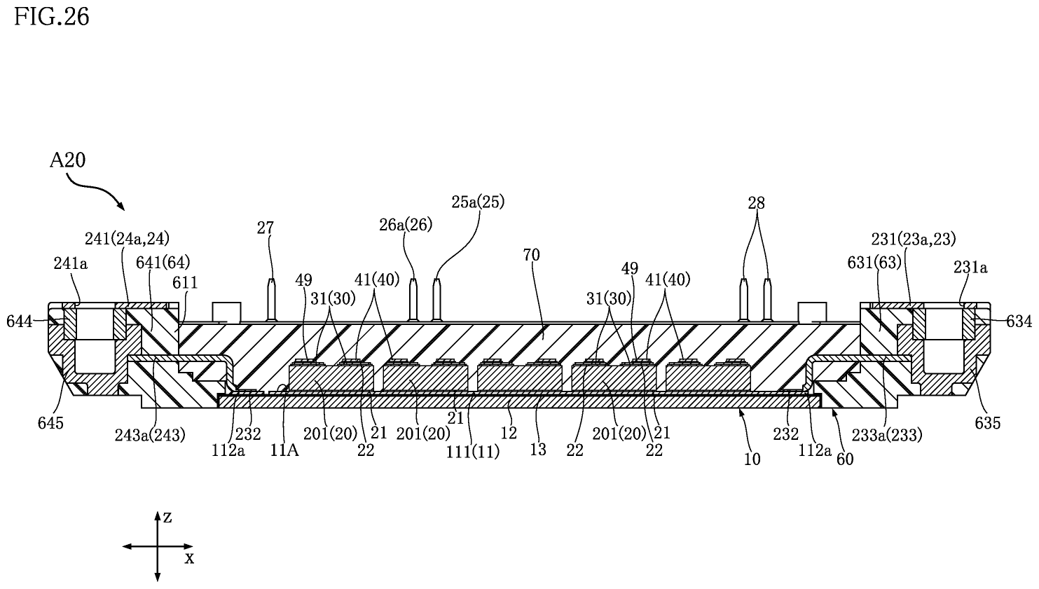

FIGS. 24 to 26 show a semiconductor device according to a second embodiment of the present disclosure. The semiconductor device A20 of the present variation differs from the semiconductor device A10 of the first embodiment mainly in configuration of the first layer 20.

In the semiconductor device A20, the first layer 20 includes a plurality of individual sections 201 separated from each other, as with the first embodiment. In the semiconductor device A20, however, each of the individual sections 201 is made larger in dimension in the first direction x than in the first embodiment. Each of the individual sections 201 supports a plurality of semiconductor elements 30. In the illustrated example, each individual section 201 supports two adjacent semiconductor elements 30 in the first direction x. Alternatively, each individual section 201 may support three or more semiconductor elements 30.

The semiconductor device A20 of the present embodiment has the same effect as the semiconductor device A10 of the first embodiment. Moreover, in the semiconductor device A20, the volume of the first layer 20 is increased by the amount corresponding to the gaps between adjacent individual sections 201 in the first direction x in the semiconductor device A10. This can further increase the heat capacity of the first layer 2. Thus, the heat generated at the semiconductor elements 30 can be diffused in the first layer 20 in the first direction x and efficiently dissipated.

The semiconductor device according to the present disclosure is not limited to the foregoing embodiments. The specific configuration of each part of the semiconductor device according to the present disclosure can be varied in design in many ways.

The present disclosure includes the embodiments described in the following clauses.

Clause 1.

A semiconductor device comprising:
a substrate including an obverse surface facing one side in a thickness direction;
a plurality of semiconductor elements located on the one side in the thickness direction with respect to the substrate and having a switching function;
a first layer located between the obverse surface and the plurality of semiconductor elements in the thickness direction and having electrical conductivity;
a second layer conductively bonding the obverse surface and the first layer to each other; and
a third layer conductively bonding the first layer and the plurality of semiconductor elements to each other.

Clause 2.

The semiconductor device according to clause 1, wherein the substrate includes a first metal layer including the obverse surface, a second metal layer located on an opposite side in the thickness direction with respect to the first metal layer, and an insulating layer interposed between the first metal layer and the second metal layer.

Clause 3.

The semiconductor device according to clause 2, wherein the first layer includes a plurality of individual sections separated from each other.

Clause 4.

The semiconductor device according to clause 3, wherein each of the plurality of semiconductor elements is supported on one of the plurality of individual sections.

Clause 5.

The semiconductor device according to clause 4, wherein the plurality of semiconductor elements are arranged at predetermined intervals in a first direction orthogonal to the thickness direction, and
each of the plurality of individual sections is larger in dimension in a second direction orthogonal to the thickness direction and the first direction than in a dimension in the

Clause 6.

The semiconductor device according to any one of clauses 2 to 5, wherein the first layer contains copper.

Clause 7.

The semiconductor device according to any one of clauses 2 to 6, wherein a thickness of the first layer is larger than a thickness of the second metal layer.

Clause 8.

The semiconductor device according to clause 7, wherein the thickness of the first layer is ten times or less than the thickness of the second metal layer.

Clause 9.

The semiconductor device according to clause 7 or 8, wherein the thickness of the first layer is 2 mm to 3 mm.

Clause 10.

The semiconductor device according to clause 9, wherein the thickness of the second metal layer is 0.3 mm to 2.0 mm.

Clause 11.

The semiconductor device according to any one of clauses 2 to 10, wherein the thickness of the first metal layer is 0.1 mm to 2.0 mm.

Clause 12.

The semiconductor device according to any one of clauses 2 to 11, wherein the first layer is made of a material having a same thermal conductivity as the second metal layer or a material having a greater thermal conductivity than the second metal layer.

Clause 13.

The semiconductor device according to any one of clauses 1 to 12, wherein the third layer contains silver.

Clause 14.

The semiconductor device according to any one of clauses 1 to 13, wherein the third layer contains sintered metal.

Clause 15.

The semiconductor device according to any one of clauses 1 to 14, wherein each of the plurality of semiconductor elements includes a semiconductor layer containing SiC.

Clause 16.

The semiconductor device according to any one of clauses 1 to 15, wherein each of the plurality of semiconductor elements includes a gate electrode, a source electrode, and a drain electrode, and
the drain electrode and the first layer are conductively bonded by the third layer.

### REFERENCE NUMERALS

A10, A11, A20: Semiconductor device 10: Substrate
11: First metal layer 11A: Obverse surface
111: First element mount section
111a: First power supply pad
112: Second element mount section 112a: Output pad
113: First conductive section 113a: Second power supply pad
113b: Slit 114: First gate section
115: First detection section 116: Thermistor mount section
117: Second gate section 118: Second detection section
12: Second metal layer 13: Insulating layer
20: First layer
201: Individual section 21: Second layer 22: Third layer
23: Power supply terminal 23a: First power supply terminal
23b: Second power supply terminal
231: External connection section
231a: Connection hole 232: Internal connection section
233: Intermediate section 233a: Base portion
233b: Standing portion
24: Output terminal 24a: First terminal section
24b: Second terminal section
241: External connection section 241a: Connection hole
242: Internal connection section
243: Intermediate section
243a: Base portion 243b: Standing portion
25: Gate terminal 25a: First gate terminal
25b: Second gate terminal
26: Element current detection terminal
26a: First detection terminal 26b: Second detection terminal
27: Power supply current detection terminal
28: Thermistor terminal
30: Semiconductor element 301: Source electrode
302: Drain electrode
303: Gate electrode 31: First element 32: Second element
40: Conductive member 41: First conductive member
42: Second conductive member
431: First gate wire 432: Second gate wire
433: Third gate wire 434: Fourth gate wire
441: First detection wire 442: Second detection wire
443: Third detection wire 444: Fourth detection wire
45: Power supply current detection wire 46: Thermistor wire
48, 49: Conductive member bonding layer 60: Case
611: First side wall
612: Second side wall 62: Mount portion
621: Mounting member
621a: Mounting hole 63: Power supply terminal base
631: First terminal base
632: Second terminal base 633: groove 634: nut
635: Intermediate member 64: Power supply terminal base
641: First terminal base
642: Second terminal base 643: groove 644: nut
645: Intermediate member 70: Sealing resin
L1: Dimension (in the first direction of individual sections)
L2: Dimension (in the second direction of individual sections)
x: First direction y: Second direction
z: Thickness direction

1. A semiconductor device comprising:
a substrate including an obverse surface facing one side in a thickness direction;
a plurality of semiconductor elements located on the one side in the thickness direction with respect to the substrate and having a switching function;
a first layer located between the obverse surface and the plurality of semiconductor elements in the thickness direction and having electrical conductivity;
a second layer conductively bonding the obverse surface and the first layer to each other; and
a third layer conductively bonding the first layer and the plurality of semiconductor elements to each other.

2. The semiconductor device according to claim 1, wherein the substrate includes a first metal layer including the obverse surface, a second metal layer located on an opposite side in the thickness direction with respect to the first metal layer, and an insulating layer interposed between the first metal layer and the second metal layer.

3. The semiconductor device according to claim 2, wherein the first layer includes a plurality of individual sections separated from each other.

4. The semiconductor device according to claim 3, wherein each of the plurality of semiconductor elements is supported on one of the plurality of individual sections.

5. The semiconductor device according to claim 4, wherein the plurality of semiconductor elements are arranged at predetermined intervals in a first direction orthogonal to the thickness direction, and
each of the plurality of individual sections is larger in dimension in a second direction orthogonal to the thickness direction and the first direction than in a dimension in the first direction.

6. The semiconductor device according to claim 2, wherein the first layer contains copper.

7. The semiconductor device according to claim 2, wherein a thickness of the first layer is larger than a thickness of the second metal layer.

8. The semiconductor device according to claim 7, wherein the thickness of the first layer is ten times or less than the thickness of the second metal layer.

9. The semiconductor device according to claim 7, wherein the thickness of the first layer is 2 mm to 3 mm.

10. The semiconductor device according to claim 9, wherein the thickness of the second metal layer is 0.3 mm to 2.0 mm.

11. The semiconductor device according to claim 2, wherein the thickness of the first metal layer is 0.1 mm to 2.0 mm.

12. The semiconductor device according to claim 2, wherein the first layer is made of a material having a same thermal conductivity as the second metal layer or a material having a greater thermal conductivity than the second metal layer.

13. The semiconductor device according to claim 1, wherein the third layer contains silver.

14. The semiconductor device according to claim 1, wherein the third layer contains sintered metal.

15. The semiconductor device according to claim 1, wherein each of the plurality of semiconductor elements includes a semiconductor layer containing SiC.

16. The semiconductor device according to claim 1, wherein each of the plurality of semiconductor elements includes a gate electrode, a source electrode, and a drain electrode, and
the drain electrode and the first layer are conductively bonded by the third layer.
